(19) United States
(12) Patent Application Publication
(10) Pub. No.: US 2015/0102264 A1
(43) Pub. Date: Apr. 16, 2015

(54) Electrically Conductive Polyamide-imide Solution for the Purpose of Creating Electrical Circuits.

(71) Applicants: Ryan David Allmandinger, Coronado, CA (US); Donald David Allmandinger, Grants Pass, OR (US)

(72) Inventors: Ryan David Allmandinger, Coronado, CA (US); Donald David Allmandinger, Grants Pass, OR (US)

(21) Appl. No.: 13/956,380

(22) Filed: Oct. 11, 2013

(51) Int. Cl. H05K 1/09

(52) U.S. Cl. CPC H05K 1/095
USPC 252/500

(57) ABSTRACT

This is the development of a new conductive ink utilizing modern plastics and processes for the purpose of improving modern circuitry. By dissolving polyamide-imide (PAI) resin and mixing it with a conductive material (such as carbon, silver, copper, or gold) we can create an electrically conductive ink that can be printed into circuitry. This method of circuit printing is far stronger and resistant to environmental forces.

### CROSS-REFERENCE TO RELATED APPLICATIONS

(Not applicable)

### STATEMENT OF FEDERALLY SPONSORED RESEARCH/DEVELOPMENT

(Not applicable)

### REFERENCE TO A “SEQUENCE LISTING,” OR A COMPUTER PROGRAM

(Not applicable)

### BACKGROUND OF THE INVENTION

The current methodology for producing non-wire wound potentiometers involves depositing a conductive ink track onto a packed powder substrate, then subjecting the substrate to a high pressure/high temperature molding process. Due to the porosity of the substrate material and the pressure of the molding process, the conductive ink track becomes distorted. An alternate method that involves injection molding a thermoplastic material over a conductive ink track would eliminate the distortion caused by porosity of the substrate, and the high pressure applied to the track. Developing a conductive ink consisting of the same thermoplastic material is necessary for maximum bonding and mold efficiency.

### BRIEF SUMMARY OF THE INVENTION

This invention describes the materials and processes used to dissolve a thermoplastic material into a liquid solution that is then mixed with conductive materials for printing conductive circuit tracks.

### BRIEF DESCRIPTION OF THE SEVERAL VIEWS OF THE DRAWING

(If Any)

### DETAILED DESCRIPTION OF THE INVENTION

The process involves dissolving a polyamide-imide (PAI) material to create a liquid solution and adding an electrical conductor.

For example:

PAI can be dissolved with the chemical called N-Methyl-2-pyrrolidone (NMP) to create a solution to which an electrical conductor is added.

Powdered or granulated carbon is one possible electrical conductor. This is added and mixed to create a homogeneous suspension. The chemical Xylene is added to control viscosity and drying rate. This mixture is an electrically conductive ink, with controllable resistance. The mass ratio of carbon to PAI determines the resistive properties of the processed mixture. Another conductive ink is created using the same PAI/NMP/Xylene solution except Silver (Ag) powder is added in place of carbon. This mixture is highly conductive (low electrical resistance) and can be used to create termination pads (electrical connection points).

1. An electrically conductive mixture consisting of liquefied polyamide-imide solution serving as a carrier for any conductive material for the purpose of creating an electric circuit.
